(19) United States
(12) Patent Application Publication
(10) Pub. No.: US 2021/0165218 A1
(43) Pub. Date: Jun. 3, 2021

(54) OPTICAL IMAGING DEVICE

(71) Applicant: SITRONIX TECHNOLOGY CORP., JHUBEI CITY (TW)

(72) Inventor: CHUAN-PIN HSIUNG, JHUBEI CITY (TW)

(21) Appl. No.: 16/920,917

(22) Filed: Jul. 6, 2020

Related U.S. Application Data
(60) Provisional application No. 62/870,899, filed on Jul. 5, 2019.
(60) Provisional application No. 62/897,537, filed on Sep. 9, 2019.

(51) Int. Cl. G02B 27/01; H05K 7/20

(52) U.S. Cl. CPC G02B 27/0149; G02B 2027/0154; H05K 7/2039; G02B 27/0101

(57) ABSTRACT

The present invention relates to an optical imaging device, which comprises a plurality of module structures assembled to form an integral device. When not assembled, each of the module structures is an independent structure, respectively. The module structures include an optical module. When assembled, the optical module reflects an image and projects the reflected image. Since the optical imaging device according to the present invention comprises the module structures for assembling to form an integral device, the optical imaging device according to the present invention is not formed integrally. Accordingly, when the optical imaging device according to the present invention is disposed in a limited space and maintenance staffs need to maintain the optical imaging device, the module structures may be disassembled so that a portion of the module structures may be withdrawn from the limited space for facilitating maintenance and lowering maintenance cost.

### FIELD OF THE INVENTION

The present invention relates generally to an imaging device, and particularly to an optical imaging device.

### BACKGROUND OF THE INVENTION

A head-up display (HUD) is an optical imaging device. It is first applied to military aircrafts for preventing pilots from reading dashboard information by bowing his head. In addition, without bowing his head, a pilot's attention or situation awareness will not be lost. Owing to its convenience and improved safety without reading dashboard by bowing a pilot's head, currently civilian aircrafts and automobiles have adopted HUDs extensively.

In the past, an automotive HUD is installed in the limited space behind the dashboard and between the dashboard and the windshield. A decorative lid is disposed above the HUD for integrating with the car design. A display window is opened on the decorative lid for allowing the HUD to project the display content to the windshield. In addition, a maintenance window is disposed below the decorative lid for a maintenance staff to maintain the HUD.

When the HUD is failed, the maintenance staff can remove the decorative lid and repair the HUD through the maintenance window below the decorative lid. Because the overall size of the main structure of the HUD is large, the main structure of the HUD is formed integrally, and the space behind the dashboard is limited, the maintenance window is smaller than the overall size of the HUD. Consequently, only simple examination and maintenance can be performed.

Since the maintenance window is smaller than the overall size of the HUD, when the malfunction of the HUD cannot be solved and the HUD should be withdrawn for complicated repair or replacement, it is required to disassemble the whole machine and electronic equipment in front of the driver seat and the front passenger seat first. Due to its serious inconvenience and time consumption, the maintenance cost is high.

Accordingly, how to design an optical imaging device that can lower the difficulty in maintenance has become a major challenge in the field.

### SUMMARY

An objective of the present invention is to provide an optical imaging device. Thanks to its nonintegral design, maintenance staffs may disassemble the optical imaging device and hence improving and lowering the difficulty in maintaining it. Accordingly, the problems in the optical imaging device according to prior art, including the requirement of disassembling many components in an automobile, the difficulty in maintenance, high maintenance cost, and long maintenance time, may be solved.

To achieve the above objective, the present invention provides an optical imaging device, which comprises a plurality of module structures assembled to form an integral device. When not assembled, each of the module structures is an independent structure, respectively. The module structures include an optical module. When assembled, the optical module reflects an image and projects the reflected image. Since the optical imaging device according to the present invention comprises the module structures for assembling to form an integral device, the optical imaging device according to the present invention is not formed integrally. Accordingly, when the optical imaging device according to the present invention is disposed in a limited space and maintenance staffs need to maintain the optical imaging device, the module structures may be disassembled so that a portion of the module structures may be withdrawn from the limited space for facilitating maintenance.

### BRIEF DESCRIPTION OF THE DRAWINGS

FIG. 1 shows a stereoscopic schematic diagram of the optical imaging device according to the first embodiment of the present invention;

FIG. 2 shows an exploded view of the optical imaging device according to the first embodiment of the present invention;

FIG. 3 shows a schematic diagram of the optical imaging device installed to an automobile according to the first embodiment of the present invention;

FIG. 4 shows a cross-sectional view of the optical imaging device according to the first embodiment of the present invention;

FIG. 5 shows a stereoscopic schematic diagram of the frame module structure according to the first embodiment of the present invention;

FIG. 6 shows another stereoscopic schematic diagram of the frame module structure according to the first embodiment of the present invention;

FIG. 7 shows a schematic diagram of the optical module structure assembled to the frame module structure according to the first embodiment of the present invention;

FIG. 8 shows a schematic diagram of the optical module structure producing backlight and projecting images according to the first embodiment of the present invention;

FIG. 9 shows a stereoscopic schematic diagram of the optical imaging device according to the second embodiment of the present invention;

FIG. 10 shows an exploded view of the optical imaging device according to the second embodiment of the present invention;

FIG. 11 shows a stereoscopic schematic diagram of the frame module structure of the optical imaging device according to the second embodiment of the present invention;

FIG. 12 shows an exploded view of the bottom-housing module structure of the optical imaging device according to the second embodiment of the present invention;

FIG. 13 shows an exploded view of the optical module structure of the optical imaging device according to the second embodiment of the present invention;

FIG. 14 shows an enlarged view of the control assembly of the optical imaging device according to the second embodiment of the present invention;

FIG. 15 shows a schematic diagram of the optical module structure assembled to the frame module structure according to the second embodiment of the present invention;

FIG. 16 shows a cross-sectional view of the optical imaging device according to the second embodiment of the present invention; and

FIG. 17 shows an exploded view of the optical imaging device according to the third embodiment of the present invention.

### DETAILED DESCRIPTION

The optical imaging device according to the prior art is installed in a limited space. For example, HUDs are installed in the limited space behind the dashboard of automobile. If the optical imaging device should be withdrawn from the limited space for replacement or complicated repair, it is required to disassemble many machine structures and electronic equipment inside the automobile first, leading to serious inconvenience and time consumption.

The optical imaging device according to the present invention is not formed integrally. Thereby, maintenance staffs may disassemble the optical imaging device according to the present invention under limited space and withdraw a portion or all structures of the optical imaging device. Hence, the difficulty in maintain the optical imaging device may be improved and lowered and thus further reducing the maintenance cost.

In the following description, various embodiments of the present invention are described using figures for describing the present invention in detail. Nonetheless, the concepts of the present invention may be embodied by various forms. Those embodiments are not used to limit the scope and range of the present invention.

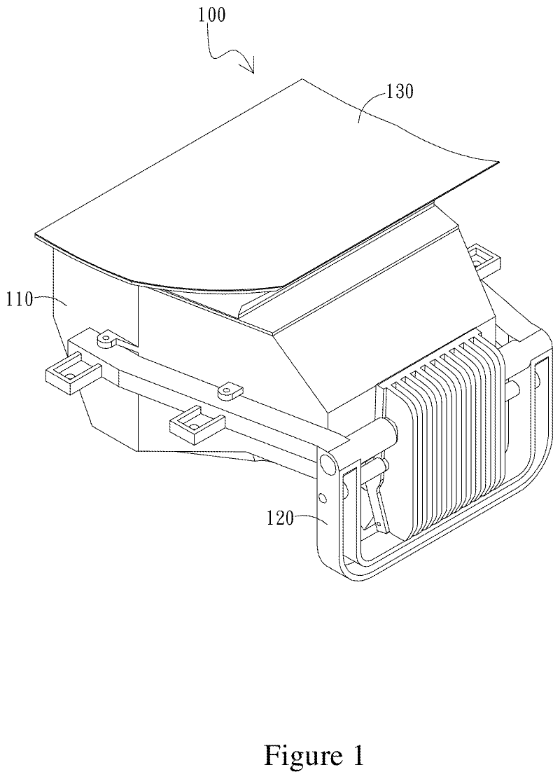

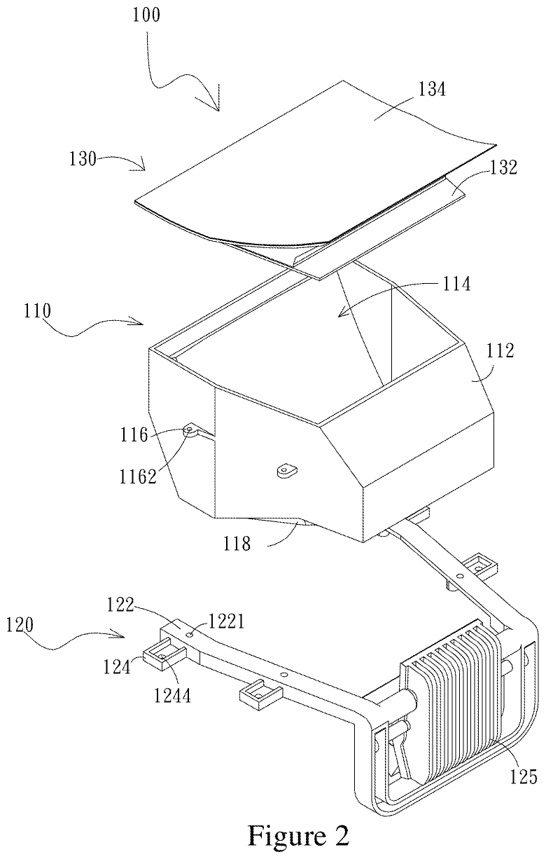

First, please refer to FIG. 1 and FIG. 2, which show a stereoscopic schematic diagram and an exploded view of the optical imaging device according to the first embodiment of the present invention. As shown in the figures, the optical imaging device 100 according to the present invention comprises a plurality of module structures, which include an optical module structure 110 and a frame module structure 120. The module structures are assembled to form an integral device. In other words, the optical module structure 110 and the frame module structure 120 are assembled to form the optical imaging device 100. Nonetheless, the optical imaging device 100 is not limited to include the optical module structure 110 and the frame module structure 120 only. When the module structures are not assembled, each of them is an independent structure. As shown in FIG. 2, when the optical module structure 110 and the frame module structure 120 are not assembled, they are independent structures, meaning that the optical imaging device 100 is not formed integrally. The module structures include an optical module 114. When the module structures are assembled to form an integral device, the optical module 114 reflects an image (not shown in the figure) and projects the reflected image.

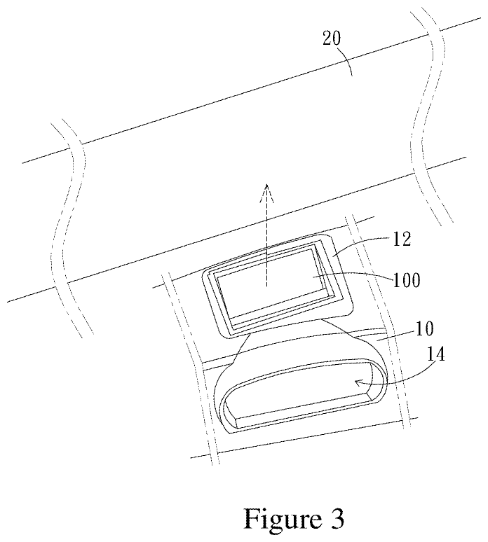

Furthermore, to separate the module structures that are assembled as whole one, one of the module structures is detached from another module structure in the module structures. The optical module structure 110 and the frame module structure 120 are assembled to form the optical imaging device 110 and installed to the space behind the dashboard 10, as shown in FIG. 3 and located between the dashboard 10 and the windshield 20 of the automobile for projecting an image to the windshield 20. The image is reflected by the windshield 20 to the driver's eyes. To withdraw the optical imaging device 100, the maintenance staff may detach the optical module structure 110 through a maintenance window 12 above the dashboard 10 or a meter installation window 14 of the dashboard 10 from the frame module structure 120. In addition, the size of each of the module structures is smaller than a predetermined size, for example, the size of the maintenance window 12 or the meter installation window 14. Thereby, the detached module structure, for example, the optical module structure 110 or the frame module structure 120, may be withdrawn from the space behind the dashboard 10 through the maintenance window 12 or the meter installation window 14.

The optical module structure 110 includes a main housing 112 and the optical module 114. The optical module 114 is disposed in the main housing 112. A plurality of fixing bases 116 are disposed on both outer sides of the main housing 112. The fixing bases 116 include a penetrating hole 1162, respectively. The frame module structure 120 includes at least one fixing frame 122. According to the present embodiment, the frame module structure 120 includes two fixing frames 122. The two fixing frames 122 correspond to both outer sides of the main housing 112, respectively. Each fixing frame 122 includes a plurality of fixing holes 1221. The fixing holes 1221 correspond to the penetrating holes 1162 of the fixing bases 116, respectively. A plurality of fixing members (not shown in the figure), for example, screws, pass through the penetrating holes 1162 and the fixing holes 1221. Thereby, the optical module structure 110 and the frame module structure 120 are assembled to form an integral device. Contrarily, removing the fixing members may separate the optical module structure 110 and the frame module structure 120. Besides, at least one fixing base 124 is disposed on the outer side of each fixing frame 122. According to the present embodiment, two fixing bases 124 are disposed on each fixing frame 122. The fixing bases 124 include a hole 1244, respectively. The fixing bases 124, as well as the fixing members such as screws, are used for fixing the frame module structure 120 to the installation space. For example, the frame module structure 120 is fixed to the space behind the dashboard 10 shown in FIG. 3 for disposing the optical imaging device 100.

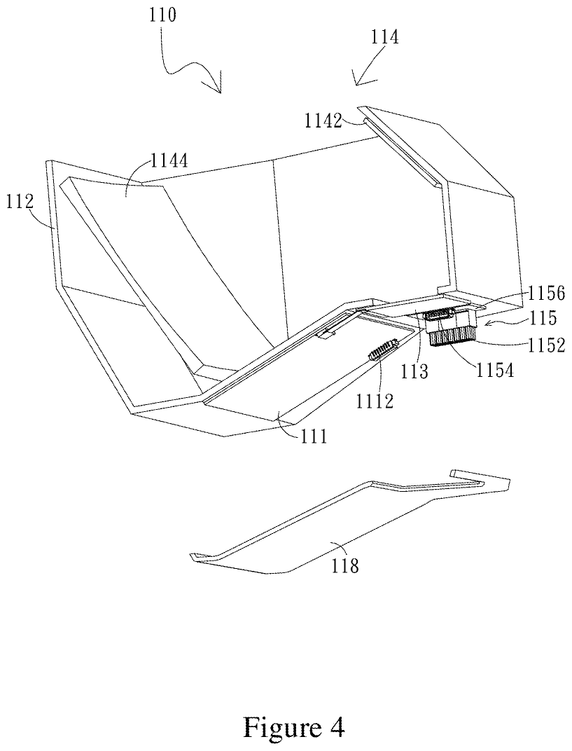

Furthermore, please refer to FIG. 4, which shows a cross-sectional view of the optical imaging device according to the first embodiment of the present invention. As shown in the figure, the optical module structure 110 further includes a mainboard 111 and a display 113 disposed at the bottom of the main housing 112. The display 113 is coupled to the mainboard 111 for receiving the display information transmitted by the mainboard 111 and displaying images. The optical module structure 110 further includes a cover 118 disposed at the bottom of the main housing 112 for covering the mainboard 111 and the display 113. In addition, the optical module structure 110 further includes a transmission module 115 disposed at the bottom of the min housing 112 and adjacent to the display 113. The transmission module 115 includes a first connection device 1152, a second connection device 1154, and a circuit board 1156. The first connection device 1154 and the second connection device 1154 are both disposed on the circuit board 1156 and connected electrically through the circuit board 1156. A third connection device 1112 is disposed on the mainboard 111. A transmission line (not shown in the figure) may be connected to the third connection device 1112 and the second connection device 1154. Thereby, the transmission module 115 is connected electrically to the mainboard 111 for transmitting power or signals. The first connection device 1152, the second connection device 1154, and the third connection device 1112 as described above may be connectors.

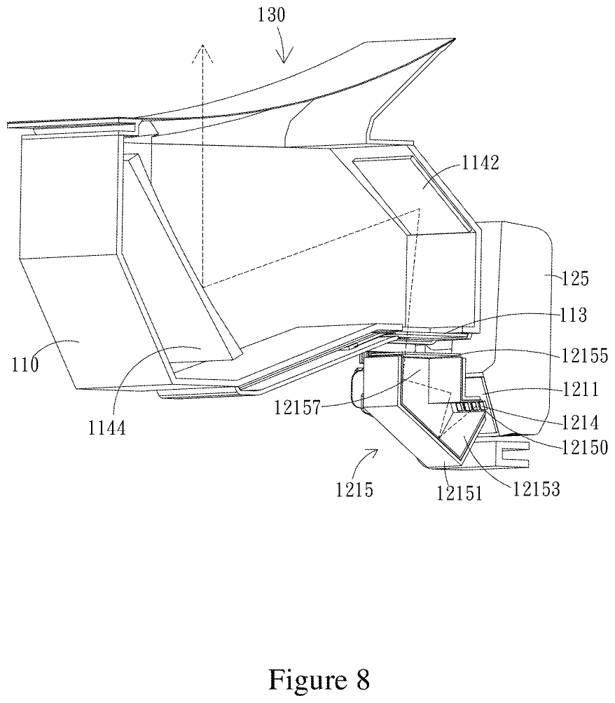

Please refer again to FIG. 4 and FIG. 8. The optical module 114 includes a reflection element 1142 and a projection element 1144 both disposed inside the main housing 112. The reflection element 1142 is opposing to the display 113 for reflecting images displayed on the display 113. The projection element 1144 is opposing to the reflection element 1142 and located on the optical reflection path of the reflection element 1142 for projecting the images reflected by the reflection element 1142. According to an embodiment of the present invention, the reflection element 1142 may be a reflective mirror; the projection element 1144 may be a spherical mirror.

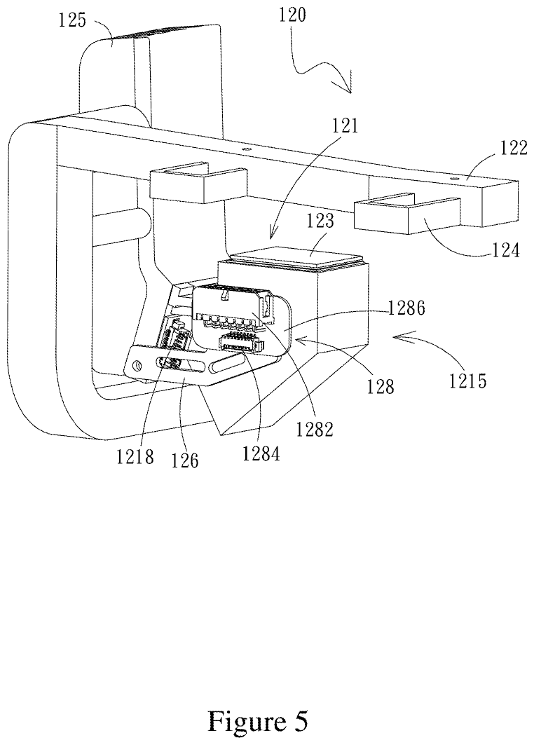

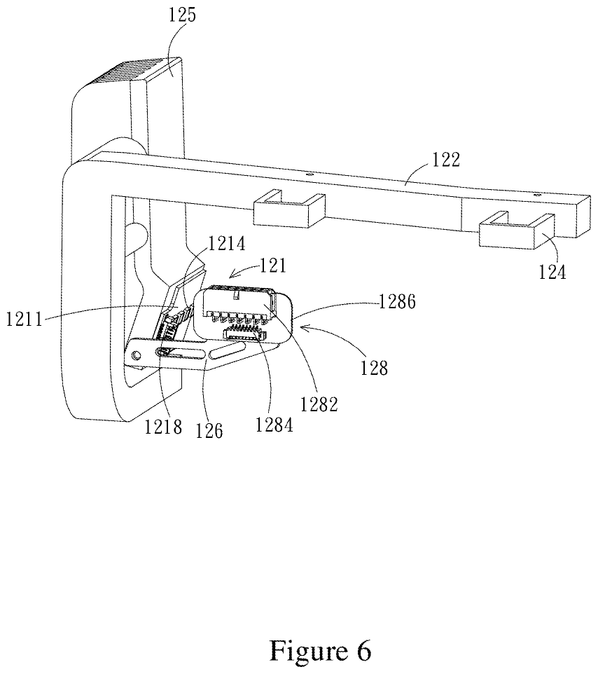

In addition, please refer to FIG. 5 and FIG. 6, which show stereoscopic schematic diagrams of the frame module structure according to the first embodiment of the present invention. As shown in the figure, the frame module structure 120 includes a backlight module 121 and a heat sink 125. The backlight module 121 provides backlight to the display 113 and is disposed on the heat sink 125. The backlight module 121 includes a circuit board 1211, a plurality of light-emitting members 1214, and a light guide structure 1215. The circuit board 1211 is disposed on one side of the heat sink 125. The light-emitting members 1214 are disposed on the circuit board 1211 for producing light as the backlight. According to an embodiment of the present invention, the light-emitting members 1214 may be light-emitting diodes (LEDs). Since the light-emitting members 1214 will generate heat in the process of producing light, the heat sink 125 may dissipate the heat generated by the light-emitting members 1214. The heat sink 125 is disposed at the fixing frame 122.

As shown in FIG. 8, a light inlet 12150 of the light guide structure 1215 is opposing to the light-emitting members 1214. A light outlet 12157 of the light guide structure 1215 is opposing to the display 113. The light-emitting members 1214 produce light, which will enter the light guide structure 1215 via the light inlet 12150. The light guide structure 1215 guides the light to the light outlet 12157 for providing the light to the display 113 as the backlight. The light guide structure 1215 includes a housing 12151, a reflection element 12153, and a diffuser 12155. The housing 12151 include the light inlet 12150 and the light outlet 12157. The reflection element 12153 is disposed inside the housing 12151, and is able to reflect the light produced by the light-emitting members 1214 and guide the light to the light outlet 12157. According to an embodiment of the present invention, the reflection element 12153 may be a reflective film or the inner surface of the housing 12151. After some surface treatment, such as polishing, the inner surface of the housing 12151 may reflect light. The diffuser 12155 is disposed at the housing 12151 and located at the light outlet 12157 and opposing to the display 113. The diffuser 12155 may diffuse light and provide uniform light to the display 113. According to an embodiment of the present invention, the diffuser 12155 may be a diffusion film.

Please refer again to FIG. 5 and FIG. 6. The frame module structure 120 may further include a frame 126 and a transmission module 128. The frame 126 is disposed on one side of the heat sink 125 and adjacent to the circuit board 1211. The transmission module 128 is disposed on the frame 126 and includes a fourth connection device 1282, a fifth connection device 1284, and a circuit board 1286. The fourth connection device 1282 and the fifth connection device 1284 are disposed on the circuit board 1286 and connected electrically through the circuit board 1286. A sixth connection device 1218 is disposed on the circuit board 1211. A transmission line (not shown in the figure) may be connected to the sixth connection device 1218 and the fifth connection device 1284. Thereby, the transmission module 128 is connected electrically to the circuit board 1211 for transmitting power to the circuit board 1211 and driving the light-emitting members 1214 to produce light. The fourth connection device 1282, the fifth connection device 1284, and the sixth connection device 1218 may be connectors.

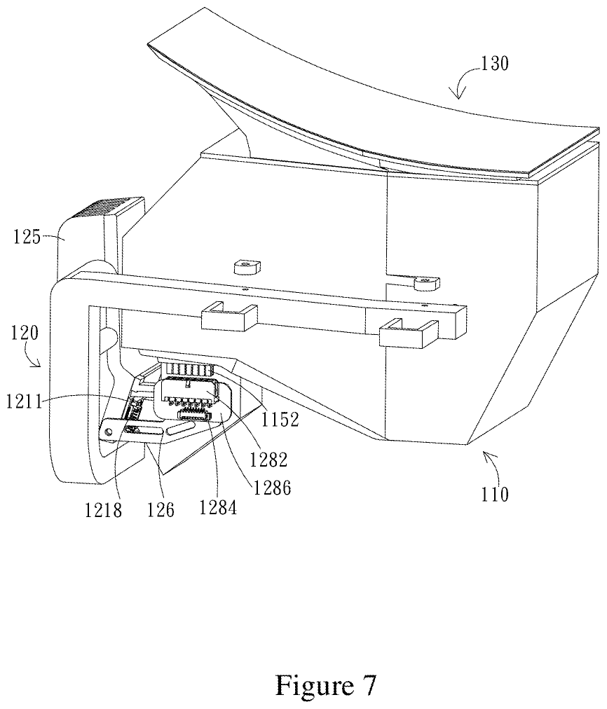

Please refer again to FIG. 4 and FIG. 7. The mainboard 111 supplies power to the light-emitting members 1214. When the optical module structure 110 is assembled to the frame module structure 120, the first connection device 1152 of the optical module structure 110 inserts to the fourth connection device 1282 of the frame module structure 120. Thereby, the power output by the mainboard 111 is transmitted to the circuit board 1211 via the third connection device 111, the second connection device 1154, the circuit board 1156, the first connection device 1152, the fourth connection device 1282, the circuit board 1286, the fifth connection device 1284, and the sixth connection device 1218. Accordingly, the power of the mainboard 111 may be supplied to the circuit board 1211 for driving the light-emitting members 1214 to produce light.

Please refer again to FIG. 1 and FIG. 2. The module structure may further include a top-housing module structure 130, which includes a top housing 132 and a lid plate 134. The top-housing module structure 130 is assembled to the optical module structure 110. The top housing 132 is located on the top of the main housing 112. The lid plate 134 is disposed on the top of the top housing 132. The lid plate 134 is transparent. The top housing 132 may be assembled to the main housing 112 by screwing or buckling. As shown in FIG. 8, the images projected by the optical module 114 may pass through the top-housing module structure 130 and be projected to the windshield 20 as shown in FIG. 3 for providing images to the driver.

To withdraw the optical imaging device 100 according to the present invention for repair or replacement, the fixing members fixed to the optical module structure 110 and the frame module structure 120 are loosened first. Then the optical module structure 110 may be separated from the frame module structure 120 and withdrawn. Before the separation, the top-housing module structure 130 is withdrawn first. Afterwards, the optical module structure 110 is withdrawn for examination or repair. Besides, the frame module structure 120 may be withdrawn for examination or repair as well. The optical imaging device 100 according to the present invention may substantially solve the problem of disassembling most components in the repair or replacement process. Consequently, the time consumption is short and maintenance cost is low.

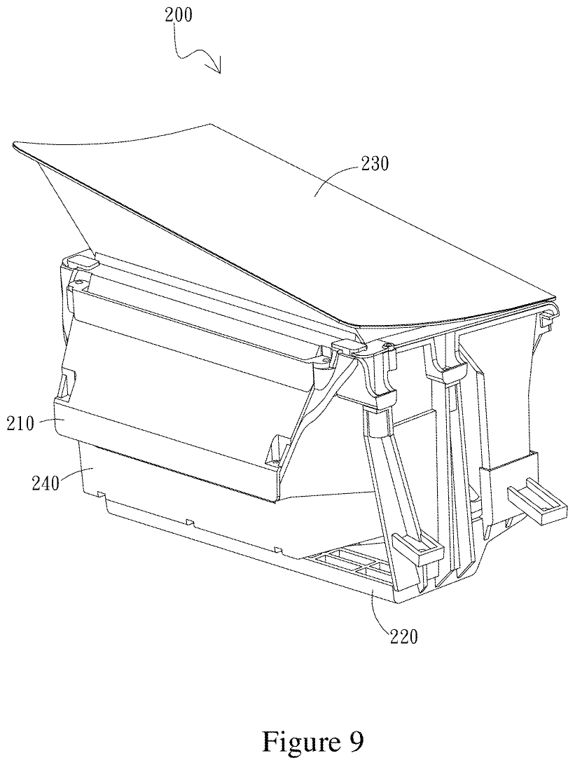

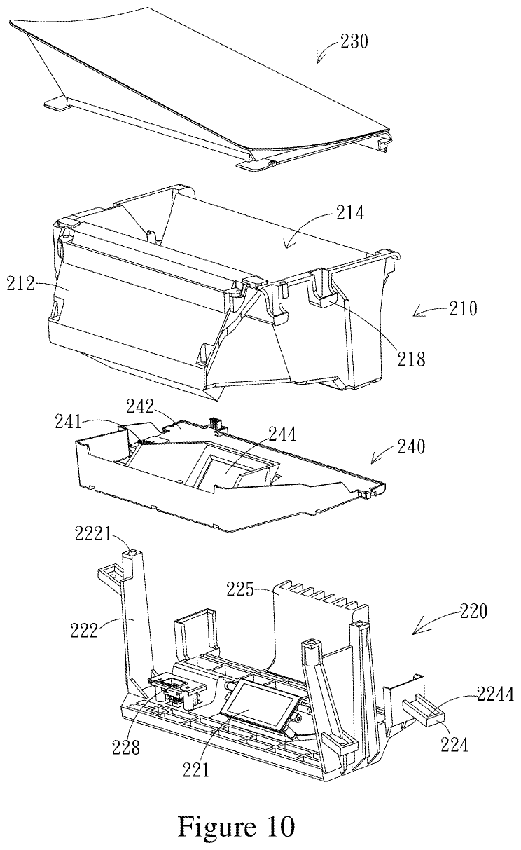

Please refer to FIG. 9 and FIG. 10, which show a stereoscopic schematic diagram of the optical imaging device according to the second embodiment of the present invention and an exploded view of the optical imaging device according to the second embodiment of the present invention. As shown in the figures, the optical imaging device 200 according to the second embodiment comprises a plurality module structures, which include an optical module structure 210, a frame module structure 220, and a bottom-housing module structure 240. The module structures are assembled to form an integral device. In other words, the optical module structure 210, the frame module structure 220, and the bottom-housing module structure 240 are assembled to form the optical imaging device 200. Nonetheless, the optical imaging device 200 is not limited to include the optical module structure 210, the frame module structure 220, and the bottom-housing module structure 240 only. When the module structures are not assembled, each of them is an independent structure. As shown in FIG. 10, when the optical module structure 210, the frame module structure 220, and the bottom-housing module structure 240 are not assembled, they are independent structures, meaning that the optical imaging device 200 is not formed integrally. The module structures include an optical module 214. When the module structures are assembled to form an integral device, the optical module 214 reflects an image (not shown in the figure) and projects the reflected image.

The optical module structure 210 includes a main housing 212 and the optical module 214. The optical module 214 is disposed in the main housing 212. A plurality of fixing bases 218 are disposed on both outer sides of the main housing 212. The fixing bases 218 include a penetrating hole (not shown in the figures), respectively. Furthermore, the bottom-housing module structure 240 includes a mainboard 242 and a display 244. The mainboard 242 further includes a transmission module 241. The frame module structure 220 includes at least one fixing frame 222. According to the present embodiment, the bottom-housing module structure 240 is fixed to the optical module structure 210 by buckling. The frame module structure 220 includes two fixing frames 222. The two fixing frames 222 correspond to both outer sides of the main housing 212 after assembling, respectively. Each fixing frame 222 includes a fixing hole 2221. The fixing holes 2221 correspond to the penetrating holes of the fixing bases 218, respectively. A plurality of fixing members, for example, screws, pass through the penetrating holes and the fixing holes 2221. Thereby, the optical module structure 210, the frame module structure 120, and the bottom-housing module structure 240 are assembled to form an integral device. Contrarily, removing the fixing members may separate the optical module structure 210 and the frame module structure 220. Besides, at least one fixing base 224 is disposed on the outer side of each fixing frame 222. According to the present embodiment, the fixing bases 224 are disposed on each fixing frame 222. The fixing bases 224 include a hole 2244, respectively. The fixing bases 224, as well as the fixing members such as screws, are used for fixing the frame module structure 220 to the installation space. For example, the frame module structure 220 is fixed to the space behind the dashboard 10 shown in FIG. 3 for disposing the optical imaging device 200.

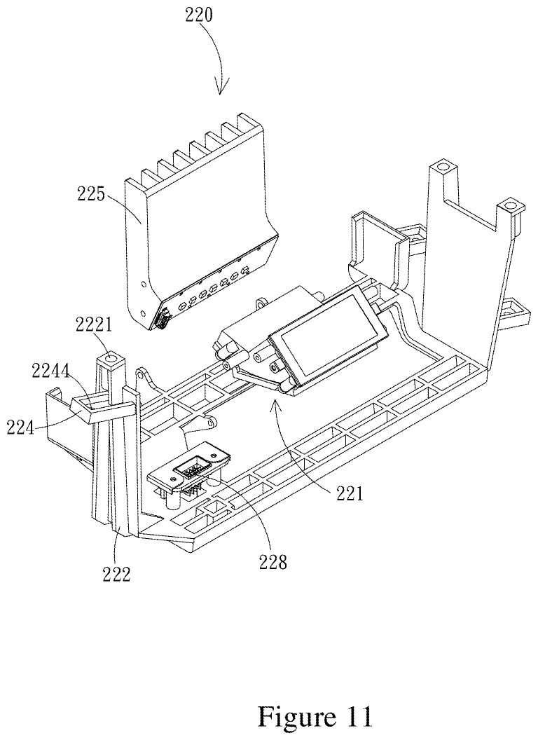

Next, please refer to FIG. 11, which shows a stereoscopic schematic diagram of the frame module structure of the optical imaging device according to the second embodiment of the present invention. As shown in the figure, the frame module structure 220 includes a backlight module 221 and a heat sink 225. The backlight module 221 provides backlight to the display 244. The method of the backlight module 221 providing backlight is identical the one according to the first embodiment. Hence, the details will not be repeated. The frame module structure 220 further includes a transmission module 228. The frame module structure 220 is connected electrically to the transmission module 241 via the transmission module 228. Thereby, the backlight module 221 and the mainboard 242 are connected.

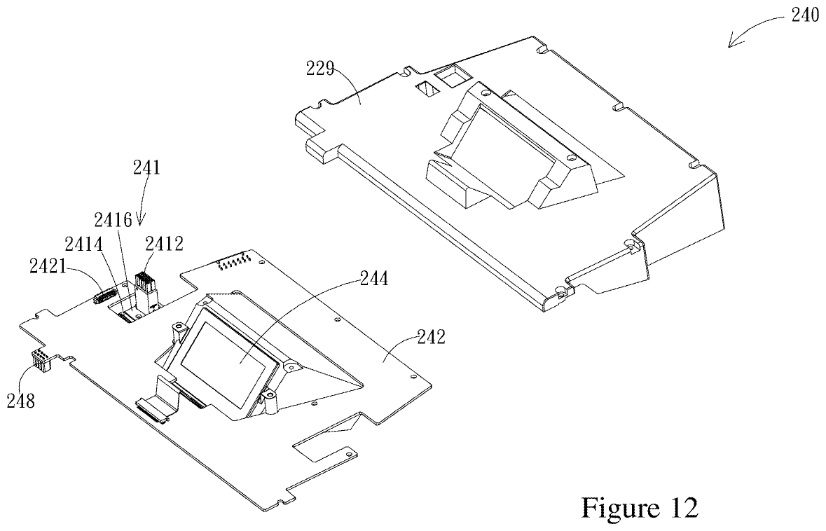

Furthermore, please refer to FIG. 12, which shows an exploded view of the bottom-housing module structure of the optical imaging device according to the second embodiment of the present invention. As shown in the figure, the bottom-housing module structure 240 further includes a housing 229, the transmission module 241, a connection device 248, the mainboard 242, and the display 244. The display 244 is connected electrically to the mainboard 242 via the transmission line. The transmission module 241 includes further a seventh connection device 2412, an eighth connection device 2414, and a circuit board 2416. The seventh connection device 2412 and the eighth connection device 2414 are both disposed on the circuit board 2416 and connected electrically through the circuit board 2416. A nineth connection device 2421 is disposed on the mainboard 242. A transmission line (not shown in the figure) may be connected to the nineth connection device 2421 and the eighth connection device 2414. Thereby, the transmission module 241 is connected electrically to the mainboard 242 for transmitting power or signals. The seventh connection device 2412, the eighth connection device 2414, and the nineth connection device 2421 as described above may be connectors.

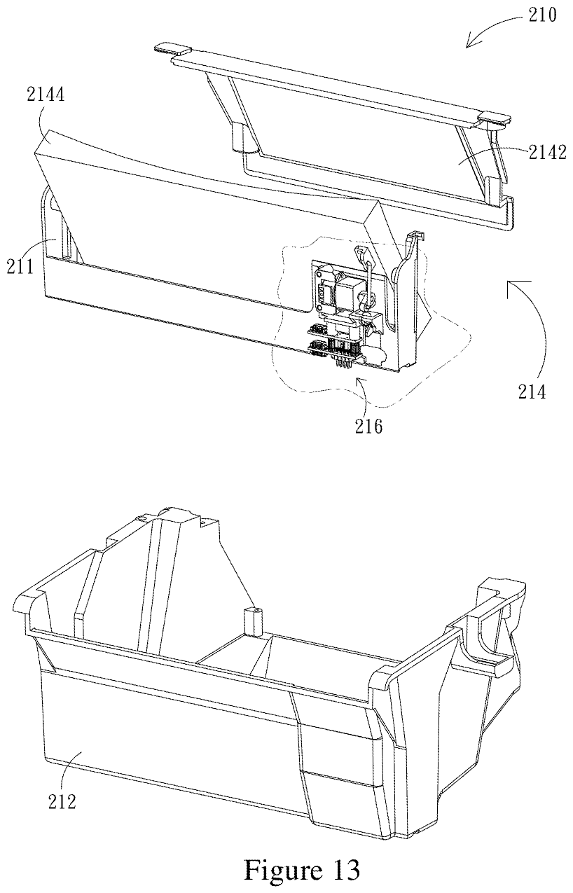

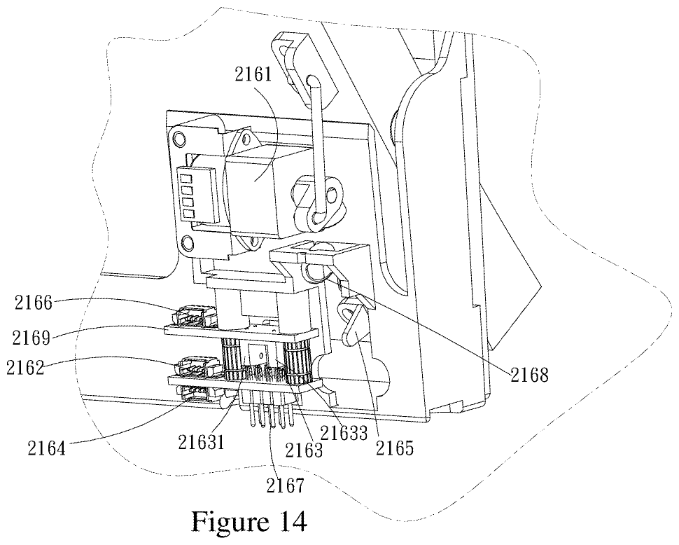

Next, please refer to FIG. 13 and FIG. 14, which show an exploded view of the optical module structure of the optical imaging device according to the second embodiment of the present invention and an enlarged view of the control assembly of the optical imaging device according to the second embodiment of the present invention. As shown in the figures, the optical module 214 includes a reflection element 2142 and a projection element 2144, a frame 211, and a control assembly 216. The reflection element 2142 and a projection element 2144 are both disposed inside the main housing 212. The reflection element 2142 is opposing to the display 244 for reflecting images displayed on the display 244. The projection element 2144 is opposing to the reflection element 2142 and located on the optical reflection path of the reflection element 2142 for projecting the images reflected by the reflection element 2142. The frame 211 is disposed inside the main housing 212. The projection element 2144 is disposed rotatably at the frame 211 for adjusting the projection angle of the projection element 2144.

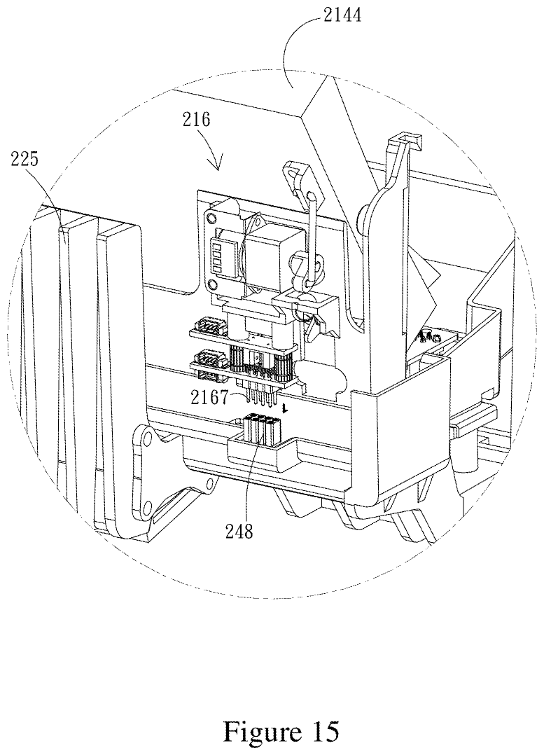

Furthermore, the control assembly 216 is disposed at the main housing 212 and connected to the projection element 2144 for controlling the rotation of the projection element 2144 and thus adjusting the projection angle of the projection element 2144. The control assembly 216 includes a driving device 2161, a first connection device 2162, a sensing module 2163, a second connection device 2164, a third connection device 2166, and a fourth connection device 2167. The driving device 2161 may drive the projection element 2144 to rotate. Please refer to FIG. 15, which shows a schematic diagram of the optical module structure assembled to the frame module structure according to the second embodiment of the present invention. As shown in the figure, the fourth connection device 2167 and the connection device 248 are connected electrically (as the arrow shown in the Figure). In other words, the fourth connection device 2167 is connected electrically to the mainboard 242 for receiving the signals form the mainboard 242 or transmitting signals to the mainboard 242. Furthermore, the connection device 2162 and the third connection device 2166 may be connected electrically via the transmission line (not shown in the figure). The second connection device 2164 may be connected electrically to the driving device 2161 via the transmission line. The first connection device 2162 and the second connection device 2164 may be connected electrically to the fourth connection device 2167 via a circuit board 2169.

The sensing module 2163 may sense the rotational position of the projection element 2144. According to an embodiment of the present invention, the sensing module 2163 may be an optical sensing module, which includes a transmitter 21631 and a receiver 21633 opposing to each other. The transmitter 21631 transmits light; the receiver 21633 may receive light. A shade member 2165 is disposed at the projection element 2144. When the projection element 2144 rotates, the projection element 2144 will drive the shade member 2165 to move. The shade member 2165 will be located at the sensing module 2163, for example, between the transmitter 21631 and the receiver 21633. Thereby, the shade member 2165 will shade the light transmitted by the transmitter 21631. The receiver 21633 will not receive the light. By judging if the receiver 21633 receives the light transmitted by the transmitter 21631, it is known if the projection element 2144 is located at the predetermined location and projects images at the predetermined angle. The sensing module 2163 senses the rotational position of the projection element 2144 and generates a sensing signal, which is transmitted to the third connection device 2166 and then to the first connection device 2162. The sensing signal is then transmitted to the mainboard 242. The mainboard 242 generates a control signal according to the sensing signal, which is transmitted to the driving device 2161 via the fourth connection device 2167 and the second connection device 2164 for controlling the driving device 2161 to rotate the projection element 2144.

Moreover, a backlash spring 2168 is connected to the frame 211 and the projection element 2144. While installing the projection element 2144 to the frame 211, a gap might occur. Thereby, when the projection element 2144 is fixed to the predetermined location and the projection angle is fixed to the predetermined angle, the projection element 2144 might shake owing to the gap, influencing the projection angle. By using the backlash spring 2168, the shake of the projection element 2144 may be avoided, which is equivalent to eliminating the gap and fixing the projection angle.

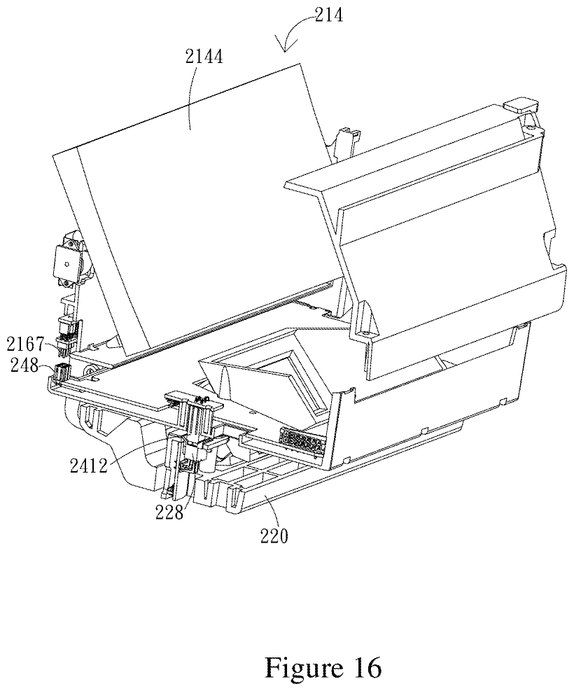

Next, please refer to FIG. 16, which shows a cross-sectional view of the optical imaging device according to the second embodiment of the present invention. As shown in the figure, according to the second embodiment of the present invention, after the module structures are assembled, the mainboard 242 may control the angle of the projection element 2144, the content of the display 244, the backlight, and the brightness of the backlight completely. No functional operation is sacrificed. Thereby, by dividing the optical imaging device into the module structures, the requirement for the overall space may be lowered effectively.

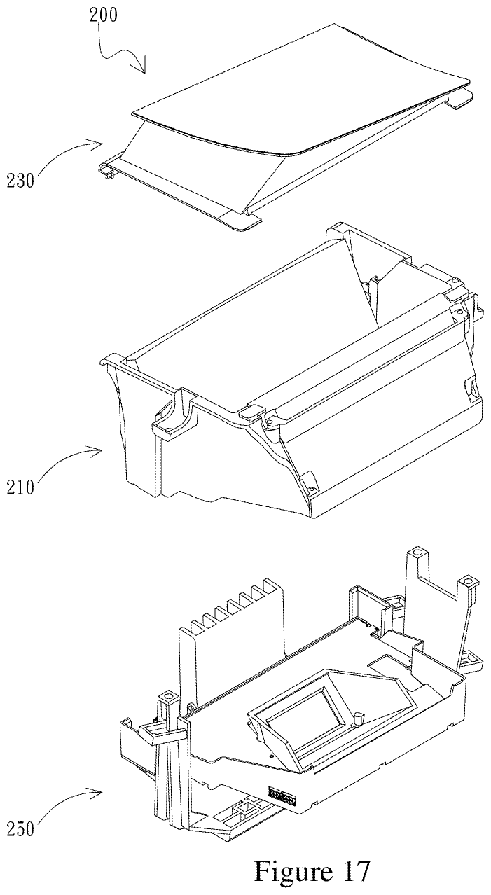

Please refer to FIG. 17, which shows an exploded view of the optical imaging device according to the third embodiment of the present invention. As shown in the figure, the bottom-housing module structure 240 and the frame module structure 220 according to the embodiment in FIG. 10 may be designed integrally and becoming another module structure 250. In other words, the circuit board and the display are disposed at the frame module structure 250. This design may reduce the number of module structures. According to the above description, the optical imaging device may be divided according to requirements and not limited to the above three embodiments.

According to the above embodiment, the optical imaging device according to the present invention is not formed integrally. Thereby, maintenance staffs may disassemble the optical imaging device according to the present invention under limited space and withdraw a portion or all structures of the optical imaging device. Hence, the difficulty in maintain the optical imaging device may be improved and lowered and thus further reducing the maintenance cost.

1. An optical imaging device, comprising:
a plurality of module structures, assemblable to form an integral device, each said module structure being an independent structure when not assembled;
wherein said module structures include an optical module; and when said module structures are assembled, said optical module reflects an image and projects the reflected image.

2. The optical imaging device of claim 1, wherein to separate the module structures assembled as said integral device, one of said module structures is detached and separated from another module structure of said module structures.

3. The optical imaging device of claim 1, wherein the size of each of said module structures is smaller than a maintenance window or a meter installation window.

4. The optical imaging device of claim 1, wherein said module structures include:
an optical module structure, including a main housing and said optical module, and said optical module disposed in said main housing; and
a frame module structure, including at least one fixing frame;
wherein said optical module structure and said frame module structure are assembled.

5. The optical imaging device of claim 4, wherein said module structures further include a top-housing module structure, assembled to said optical module structure, and located on a top of said main housing.

6. The optical imaging device of claim 4, wherein said optical module structure further includes:
a mainboard; and
a display, coupled to said mainboard and displaying said image.

7. The optical imaging device of claim 4, wherein said frame module structure further includes a backlight module to provide a backlight.

8. The optical imaging device of claim 4, wherein said frame module structure further includes a heat sink, and said backlight module is disposed on said heat sink.

9. The optical imaging device of claim 4, wherein said frame module structure further includes:
a mainboard; and
a display, coupled to said mainboard and displaying said image.

10. The optical imaging device of claim 4, wherein said module structures further include a bottom-housing module structure, including a bottom housing, assembled to said optical module structure, and located at a bottom of said main housing.

11. The optical imaging device of claim 10, wherein said bottom-housing module structure further includes:
a mainboard; and
a display, coupled to said mainboard and displaying said image.

12. The optical imaging device of claim 4, wherein said optical module includes:
a reflection element, disposed in said main housing, and reflecting said image;
a frame, disposed in said main housing;
a projection element, disposed at said frame, and projecting said image reflected by said reflection element; and
a control assembly, disposed in said main housing, connected to said projection element, and controlling the rotation of said projection element for adjusting a projection angle of said projection element for projecting said image.
